(19) United States
(12) Patent Application Publication
(10) Pub. No.: US 2007/0013057 A1
(43) Pub. Date: Jan. 18, 2007

(54) Multicolor LED assembly with improved color mixing

(76) Inventor: Joseph Mazzochette, Cherry Hill, NJ (US)

Correspondence Address: PATENT DOCKET ADMINISTRATOR;LOWENSTEIN SANDLER PC, 65 LIVINGSTON AVENUE, ROSELAND, NJ, 07068, US

(21) Appl. No.: 11/445,611

(22) Filed: Jun. 2, 2006

Related U.S. Application Data
(63) Continuation-in-part of application No. 10/822,236, filed on Apr. 9, 2004.
(63) Continuation-in-part of application No. 10/638,579, filed on Aug. 11, 2003, now Pat. No. 7,095,053.
(60) Provisional application No. 60/467,857, filed on May 5, 2003.

(51) Int. Cl. H01L 23/34

(52) U.S. Cl. 257/723

(57) ABSTRACT

In accordance with the invention, a multicolor LED assembly with improved color mixing comprises an assembly of closely-packed LED dice of different colors packaged for high temperature operation and arranged to minimize same-color adjacency to promote color mixing. The assembly of dice is encapsulated in a dispersive medium such as a transparent medium with entrained dispersive particles. The packaged assembly preferably includes a layer having light dispersing particles deposited directly on the LED.

### CROSS REFERENCE TO RELATED APPLICATIONS

This application is a continuation-in-part of U.S. patent application Ser. No. 10/822,236 filed on Apr. 9, 2004 entitled, “Illumination Devices Comprising White Light Diodes and Diode Arrays and Method and Apparatus for Making Them” This application is also a continuation-in-part of U.S. patent application Ser. No. 10/638,579 filed on Aug. 11, 2003 entitled, “Light Emitting Diodes Packaged for High Temperature Operation”, which application is hereby incorporated herein by reference. U.S. patent application Ser. No. 10/638,579 in turn claims the benefit of U.S. Provisional Application Ser. No. 60/467,857, “Light Emitting Diodes Packaged for High Temperature Operation”, filed on May 5, 2003. The 10/822,236, 10/638,579 and 60/467,857 applications are incorporated by reference herein.

### FIELD OF THE INVENTION

This invention relates to assemblies of light emitting diodes (LEDs) and, in particular, to assemblies of LEDs of different color where the assemblies are configured to mix the different colored light and thus reduce the tendency of single colors to dominate particular viewing angles.

### BACKGROUND OF THE INVENTION

Light emitting diodes (LEDs) are being used as light sources in an increasing variety of applications extending from communications and instrumentation to household, automotive and visual displays. In many of these applications color variability is advantageous or required. LEDs have great promise for color variable applications because of their rapid switching time, small size, high reliability, long life and simplicity of color control.

A common color variable LED assembly combines red, green and blue (RGB) LEDs in an RGB assembly. Color can be varied by switching on different colors or different combinations of colors.

Unfortunately, conventional multi-colored LEDs, including conventional RGB assemblies, suffer from poor color mixing. Because the LED die emit considerable heat, the LED die are typically widely spaced for heat dissipation. As a consequence, die of different color are spaced apart, and viewers see different colors from different viewing directions.

FIG. 1, which is a schematic cross-section of a conventional RGB assembly 10, is useful in understanding poor color mixing. The assembly 10 comprises red, green and blue LED die 11R, 11G and 11B, respectively disposed on a mounting base 12 and encapsulated in a transparent dome 13. The die can be mounted within a surface cavity (not shown) in the base 12. In the particular arrangement illustrated, green light from die 11G dominates viewing angles on the left side of the assembly, blue light from 11B dominates views from the right side and red light from 11R dominates central viewing.

It is desirable for the light produced by a multi-color array to appear uniform and the detection of individual colors be minimized. Accordingly there is a need for a multi-color LED assembly with improved color mixing.

### SUMMARY OF THE INVENTION

In accordance with the invention there is provided an assembly of multicolor light emitting diodes (LEDs) packaged for improved color mixing. The assembly comprises a thermally conductive mounting base including a surface cavity. A plurality of LED die is mounted within the cavity overlying the mounting base. Each of the respective die of the plurality of LEDs emit light of respectively different colors. The assembly of the die is encapsulated in a dispersive medium, such as a transparent medium with entrained dispersive particles to randomly mix light from different LED dies.

### BRIEF DESCRIPTION OF THE DRAWINGS

The advantages, nature and various additional features of the invention will appear more fully upon consideration of the illustrative embodiments now to be described in detail in connection with the accompanying drawings. In the drawings:

FIG. 1 is a schematic cross section of a conventional RGB LED assembly useful in understanding the problem to which the invention is addressed;

FIG. 2 is schematic cross section of a multicolor LED assembly, according to an embodiment of the present invention.

FIG. 3 is a top view of a multicolor LED assembly, of FIG. 2.

FIG. 4A, FIG. 4B, and FIG. 4C illustrate schematic cross sections of a multicolor LED assembly according to an alternative embodiment of the present invention.

FIG. 5 illustrates a schematic cross section of a multicolor LED assembly in accordance to another embodiment of the present invention.

FIG. 6 illustrates a schematic cross section of a multicolor LED assembly in accordance to another embodiment of the present invention.

FIG. 7 is a schematic cross section illustrating various advantageous features of LTCC-M packaging in accordance with an embodiment of the present invention

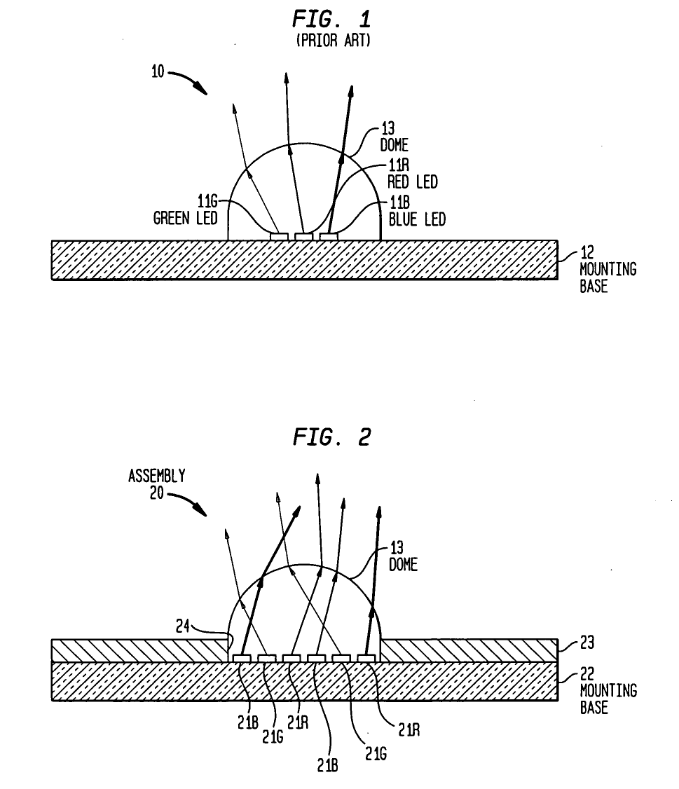

It is to be understood that these drawings are for purposes of illustrating the concepts of the invention and are not to scale.

### DETAILED DESCRIPTION OF THE INVENTION

The description is divided into two parts. Part I describes the structure and features of multicolor LED assemblies packaged and configured for enhanced color mixing of light from different color LEDs. Part II describes details of the LTCC-M technology that may advantageously be used in packaging the assembly.

I. Multicolor LED Assemblies With Improved Color Mixing

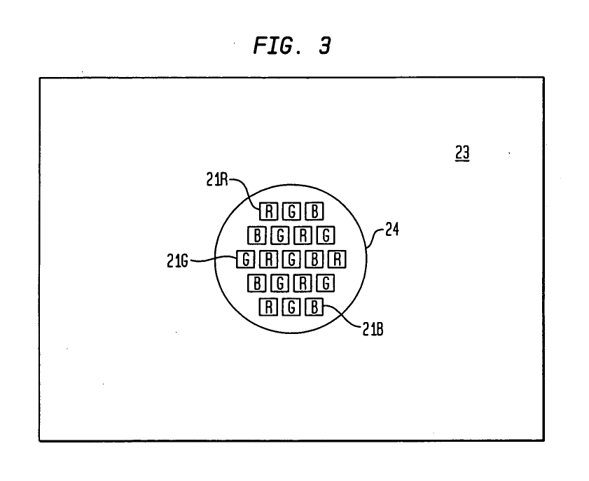

Referring to the figures, FIG. 2 is a schematic cross-section of a multicolor LED assembly 20 and FIG. 3 is a top view of the assembly 20 of FIG. 2, according to an embodiment of the present invention. The assembly 20 comprises different color LEDs (e.g. 21R, 21G, 21B) that are packaged and configured for enhanced mixing of the light emitted from the different color LEDs. The assembly 20 comprises a mounting base 22 preferably made of metal, an overlying layer 23 preferably made of ceramic with an opening defining a surface cavity 24. A plurality of LED die (21R, 21G, 21B) are mounted in the cavity 24 and in thermal contact with the base 22 by either direct contact with the base or through a thin intervening thermally-conductive layer (not shown). Preferably, the base metal layer 22 is composed of a material having a coefficient of thermal expansion that closely matches that of the one or more LED die 21 Optionally, the base 22 can, in turn, include an underlying thermal connection pad (not shown) to further cool down any heat emitted from the LED die. The die assembly is encapsulated within a transparent encapsulation dome 13.

Because the metal base 22 exhibits high thermal conductivity, the LED die 21R, 21G, 21B of assembly 2 maybe mounted in a “closely-packed” assembly, that can achieve part-to-part (die to die) gaps in the range between 25 and 2,000 microns with an optimal range between 125 to 500 microns. The minimum practical spacing between die is 25 microns. This limit is due to practical limits in the LED die size variation and in the limit in the accuracy of die placement equipment. The maximum spacing is preferred to be 2000 microns in order to achieve the improved color mixing.

The assembly of LED die may comprise one or more die of each of a plurality of colors. For example, in an RGB assembly, the assembly 21 may include one or more red die 21R, one or more green die 21G, and one or more blue die 21B. The die are configured in the assembly to minimize same-color adjacency. Thus, for example, as shown in FIG. 2 and FIG. 3 the assembly 21 is arranged such that each successive die is a different color than its neighbor.

Advantageously, however, the assembly is two dimensional. In a two dimensional assembly it is not always possible to avoid same color adjacency but it is desirable to keep the incidence of same-color adjacency low. The percent (%) of adjacency can be calculated by dividing the total edge adjacent area of the color die with the total edge area of the colored die. Lowest same color adjacency in an LED array is achieved if there are no die of the same color with adjacent die edges. The upper end of the “low incidence of same-color adjacency” range would be where less than 60% of the die have same color adjacent edges. The two-dimensional assembly of LED die of FIG. 2 and FIG. 3 has a low incidence of same color adjacency, preferably less than 60% of the LED die edges are adjacent to die emitting the same color.

The combination of close-packing, die of different colors, and minimization of same-color adjacency produces an assembly with substantially improved color mixing as measured by detecting the light radiation using a spectro-radiometer with a view limiting aperture. This method measures the variation in x-y coordinate (according to the CIE standard calorimetric system) as a function of viewing angle. Measurements are best made by scanning the source directly with the detector.

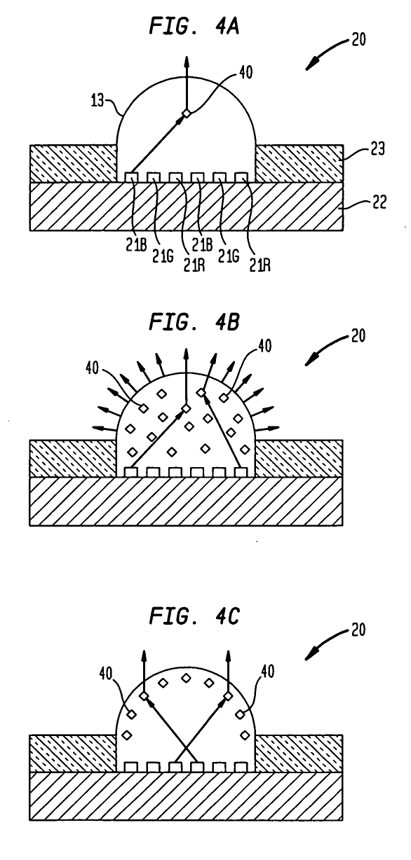

FIG. 4A, FIG. 4B, FIG. 4C illustrate, in schematic cross section, modified forms of the multicolored LED assembly of FIG. 2, wherein the transparent encapsulant 13 includes light dispersive elements 40 such as dispersive particles distributed within the encapsulant. The light dispersive elements 40 can be particles of material with an index of refraction sufficiently different from that of the encapsulant material to scatter incident light. For typical encapsulants, the light dispersive elements 40 can be particles of fumed silica, silicon, titanium oxide, indium oxide or tin oxide, among others. The particles can typically be spherical, pyramidal, flat or other advantageous shapes. The particle material and shape should be selected to minimize light loss due to absorption and total internal reflection. The particles preferably have effective diameters in the range 0.01 to 100 microns. The presence of the light dispersive elements 40 randomly mixes the light produced by each of the different LED die 21 which in turn further increases color mixing, color uniformity and reduces bright spots. Referring to FIG. 4A, there is shown a multi-colored LED assembly 20 including a scattering particle 40 within the encapsulated material 13. According to one embodiment of the present invention, as the light emitted from LED 21B hits the particle 40, it deflects or deviates away from its direction as can be seen clearly in FIG. 4A. The degree of deflection does not have to be high and will preferably range from 2° to 25° in order to achieve good color mixing. The deflection may be achieved by refraction or reflection. Complex particle shape or a graded refractive index will improve the desired random color mixing. Referring to FIG. 4B there is shown a multi-colored LED assembly 20 including multiple scattering particles 40 distributed throughout the encapsulant material 13, according to another embodiment of the present invention. Similar to FIG. 4A, light emitted from the multiple LED's 21 in FIG. 4B deflects away from its normal direction. The degree of deflection does not have to be high and will preferably range from 2° to 25° in order to achieve good color mixing. The deflection may be achieved by refraction or reflection. Complex particle shape or a graded refractive index will improve the desired random color mixing.

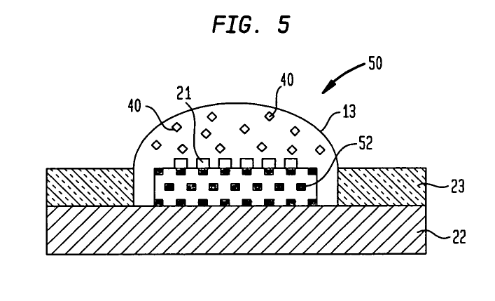

Referring to FIG. 4C, there is shown a multi-colored LED assembly 20 including multiple light dispersing particles 40 distributed only near the boundary surface of the encapsulant material 13, according to an alternative embodiment of the present invention. The degree of deflection does not have to be high and will preferably range from 2° to 25° in order to achieve good color mixing. The deflection may be achieved by refraction or reflection. Complex particle shape or a graded refractive index will improve the desired random color mixing. Distributing the dispersing particles at the encapsulant boundary will reduce the amount of light that is reflected directly back to the LED source. Consequently, light extraction from the assembly will improve. According to another embodiment of the present invention, as shown in FIG. 5, the multicolor multicolor LED package assembly 50 preferably comprises an isolator or interposer 52 disposed between the mounting base 22 and one or more LED die 21. Advantageously, the isolator 52 comprises a material having a thermal coefficient of expansion (TCE) that closely matches that of the one or more LED die 21, thus managing any thermal mechanical stresses caused by the heat generated by the LED die. Suitable TCE-matching materials that may be used in accordance with the present invention include, but are not limited to, copper—molybdenum—copper (CuMoCu), tungsten—copper (WCu), aluminum—silicon—carbide (AlSiC), aluminum nitride (AIN), silicon (Si), beryllim oxide (BeO), diamond, or other material that has a TCE that is matched to that of the LED. The one or more LED dice 21 may be attached to the isolator 52 using any suitable attachment means or material including but not limited to conductive epoxy, solder, brazing, mechanical means.

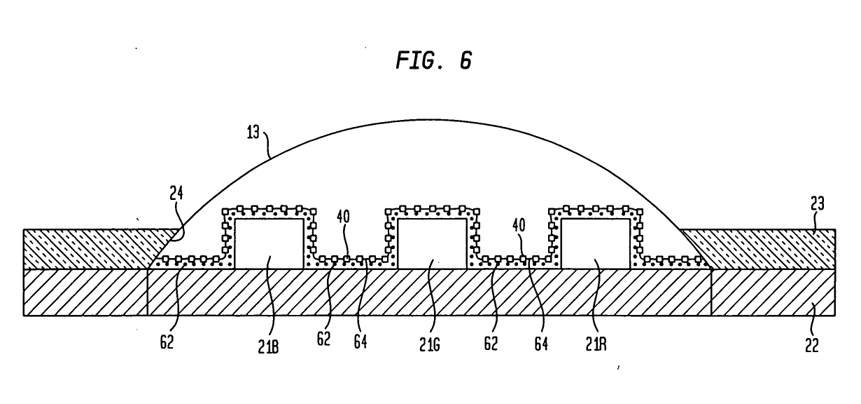

FIG. 6 illustrates a multicolored LED array assembly 60 in which several LEDs 21, are placed inside the cavity 24 and in thermal contact with the base 22 with the overlying layer 23 as described above. A transparent adhesive layer 62 is placed on top of the multiple LED bodies 21 and a layer 64 of light dispersing particles 40 is adhered overlying and over the sides of the bodies 21. In fabrication, all LEDs 21 can simultaneously be coated with a tacky transparent adhesive 62. The particles 40 can attach to the tacky layer 62 creating a closed packed dense film layer 64 of self-limiting thickness. The assembly 60 comprising wire bonded LEDs 21 can then optionally be sealed as by covering with a transparent encapsulant dome 13 as described above. Although, not shown, a reflective layer of metal such as silver may preferably be overlying the base 22.

The tacky transparent material 62 advantageously is a resin that has an index of refraction (IR) between the LED semiconductor material (3.0-2.8) and the lighting dispersing particles 40 (1.77). The tackiness of the material is due to a b-stage or partially cured resin. Tackiness is needed to adhere particles 40. The material 62 will also serve as a buffer layer as the photons exit the LED junctions and couple with the light dispersing particle 40 such as a frequency converting phosphor for improved color rendering in a white light part. The white light is being produced from blue LED 21B, or green LED 21G, red LED 21R or LEDs with other color emissions such that phosphor converts light from the at least blue LED 21B. The converting phosphor can be particles of YAG:Ce or BOSE (Europium activated Barium Orthosilicates, such as those manufactured by Litec, LLL GmbH). This structure will maximize the extraction of photons from LEDs 21 and produce a uniform color light distribution. Alternatively, the light dispersing particles 40 deposited on the tacky adhesive can be particles 62 of fumed silica, silicon, titanium oxide, indium oxide or tin oxide, among others. The particles can typically be spherical, pyramidal, flat or other advantageous shapes. The particle material and shape should be selected to minimize light loss due to absorption and total internal reflection. The particles preferably have effective diameters in the range 0.01 to 100 microns. The presence of the light dispersive elements 40 randomly mixes the light produced by each of the different LED die 21 which in turn further increases color mixing, color uniformity and reduces bright spots.

The preferred tacky transparent materials include but are not limited to partially cured silicones or fully cured gel-like silicones with high refractive index (e.g., GE Silicones IVS5022 or Nusil Gel-9617-30). The silicones can include micro amino emulsions, elastomers, resins and cationics. Other useful polymeric resins include butyrals, cellulosic, silicone polymers, acrylate compounds, high molecular weight polyethers, acrylic polymers, co-polymers, and multi-polymers. The index of refraction of the above-mentioned materials can be tailored for optical matching.

Preferably the illumination device is composed of at least one LED, at least one layer, preferably a monolayer of transparent tacky material and at least one layer or layer comprising light dispersing particles. The term “monolayer” as used herein refers to a thin film or coating that is less than 25 microns thick. Other layers that can be added include an amorphous film (no definite crystal structure) that conforms or molds to its surroundings. The surface of the LED crystal can be modified by deposition of a monolayer, which may change the reactivity of the LED surface with respect to particles. A surfactant can be used. Surfactants (or surface active agents) are special organic molecules which are made up of two sections: the hydrophilic part (usually ionic or nonionic) which likes water and the hydrophobic part (usually a hydrocarbon chain) which likes oil. The interfacial layer formed as a result of this is usually a monolayer and allows the particles to adhere to the LED. These monolayers can play an important role in the adhesion process.

The layer or monolayer of light dispersing particles can be a layer of particles or an organic film layer that includes the particles. The adhesion mechanism that holds the particle layer together can involve many mechanisms of particle-to-particle bonding. Among them are mechanical interlocking, molecular forces, Vanderwaals adhesion forces, capillary, electrostatic, magnetic, and free chemical forces. In most cases, the strength of the particle-to-particle bond depends on the contact pressure and surface area of contact between particles. The key is to create a dust or mist comprising the particles over the tacky film.

The invention may now be more clearly understood by consideration of the following specific examples.

### EXAMPLES

Assemblies as shown in FIGS. 2, 3 and 4 and 5 can be fabricated using the low temperature co-fired ceramic-on-metal (LTCC-M) technique described in Part II. The LTCC-M technique can be used to fabricate the metal base. The LED die can be encapsulated by an epoxy such as Dymax 9615 epoxy. The light dispersing elements can be 0.01 to 100 micron fumed silica or titanium oxide.

II. LTCC-M Packaging

Multilayer ceramic circuit boards are made from layers of green ceramic tapes. A green tape is made from particular glass compositions and optional ceramic powders, which are mixed with organic binders and a solvent, cast and cut to form the tape. Wiring patterns can be screen printed onto the tape layers to carry out various functions. Vias are then punched in the tape and are filled with a conductor ink to connect the wiring on one green tape to wiring on another green tape. The tapes are then aligned, laminated, and fired to remove the organic materials, to sinter the metal patterns and to crystallize the glasses. This is generally carried out at temperatures below about 1000° C., and preferably from about 750-950° C. The composition of the glasses determines the coefficient of thermal expansion, the dielectric constant and the compatibility of the multilayer ceramic circuit boards to various electronic components. Exemplary crystallizing glasses with inorganic fillers that sinter in the temperature range 700 to 1000° C. are Magnesium Alumino—Silicate, Calcium Boro—Silicate, Lead Boro—Silicate, and Calcium Alumino—Boricate.

More recently, metal support substrates (metal boards) have been used to support the green tapes. The metal boards lend strength to the glass layers. Moreover since the green tape layers can be mounted on both sides of a metal board and can be adhered to a metal board with suitable bonding glasses, the metal boards permit increased complexity and density of circuits and devices. In addition, passive and active components, such as resistors, inductors, and capacitors can be incorporated into the circuit boards for additional functionality. Where optical components, such as LEDs are installed, the walls of the ceramic layers can be shaped and / or coated to enhance the reflective optical properties of the package. Thus this system, known as low temperature cofired ceramic-metal support boards, or LTCC-M, has proven to be a means for high integration of various devices and circuitry in a single package. The system can be tailored to be compatible with devices including silicon-based devices, indium phosphide-based devices and gallium arsenide-based devices, for example, by proper choice of the metal for the support board and of the glasses in the green tapes.

The ceramic layers of the LTCC-M structure are advantageously matched to the thermal coefficient of expansion of the metal support board. Glass ceramic compositions are known that match the thermal expansion properties of various metal or metal matrix composites. The LTCC-M structure and materials are described in U.S. Pat. No. 6,455,930, “Integrated heat sinking packages using low temperature co-fired ceramic metal circuit board technology”, issued Sep. 24, 2002 to Ponnuswamy, et al and assigned to Lamina Ceramics. U.S. Pat. No. 6,455,930 is incorporated by reference herein. The LTCC-M structure is further described in U.S. Pat. No. 5,581,876, 5,725,808, 5,953,203, and 6,518,502, all of which are assigned to Lamina Ceramics and also incorporated by reference herein.

The metal support boards used for LTCC-M technology do have a high thermal conductivity, but some metal boards have a high thermal coefficient of expansion, and thus a bare die cannot always be directly mounted to such metal support boards. However, some metal support boards are known that can be used for such purposes, such as metal composites of copper and molybdenum (including from 10-25% by weight of copper) or copper and tungsten (including 10-25% by weight of copper), made using powder metallurgical techniques. Copper clad Kovar®, a metal alloy of iron, nickel, cobalt and manganese, a trademark of Carpenter Technology, is a very useful support board. AlSiC is another material that can be used for direct attachment; as can aluminum or copper graphite composites.

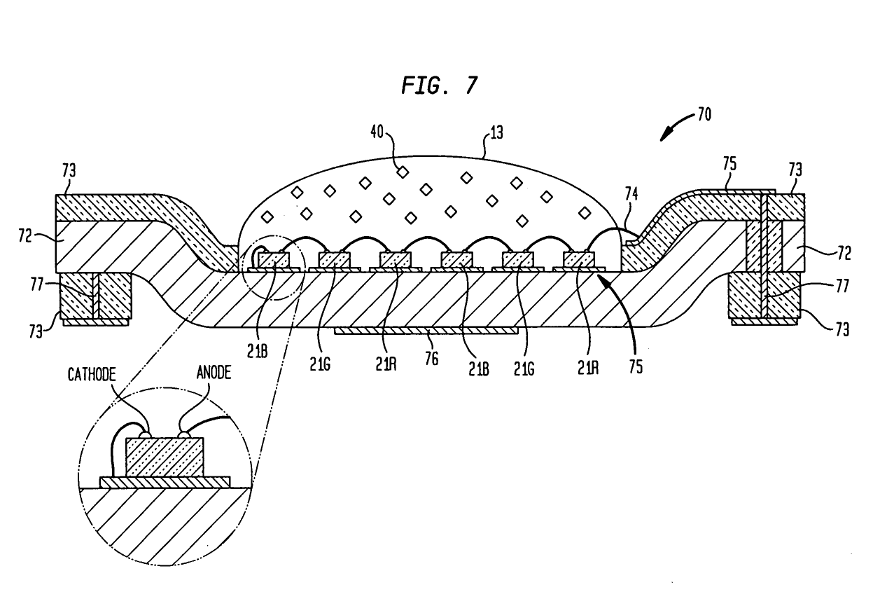

In the simplest form, LTCC-M technology is used to provide an integrated package for a semiconductor component and accompanying circuitry, wherein the conductive metal support board provides, a heat sink for the component. Referring to FIG. 7, there is shown a schematic cross-section of the LTCC-M packaging 70 including a bare LED die 21 mounted onto a metal base 72 through a bonding pad 75. Also, included in the assembly packaging 70 are multiple dispersing particles 40 distributed throughout the encapsulant 13. The particles 40 may be distributed in various ways including near the boundary surface of the enacapsulant 13 as shown in FIG. 4A. The metal base 72 is coated with LTCC 733 The LTCC-M packaging 70 has high thermal conductivity to cool the die. In such case, the electrical signals required to operate the component can be connected to the die 21 from the LTCC 73. In FIG. 7, wire bond 74 serves this purpose. Indirect attachment to the metal support board can also be used. In this package, all of the required components are mounted on a metal base 71, incorporating passive components such the bonding pads (pair of electrodes) 75, thermal connective pads 76 and conductive vias 77 and resistors into the multilayer ceramic portion, to connect the various components, i.e., semiconductor components, circuits, heat sink and the like, in an integrated package. The package can be hermetically sealed with a lid or encapsulant. Specifically, a pair of electrodes lie on top of the die 71 and one electrically insulated from the metal base 72. The thermal conductive pads 77 are mounted to the base 72 to dissipate heat from the LED die. The conductive vias 77 are insulated from the base 72 and are used to electrically connect the electrodes to the base 72 with the wire bonds 74.

For a more complex structure having improved heat sinking, the integrated package of the invention combines a first and a second LTCC-M substrate. The first substrate can have mounted thereon a semiconductor device, and a multilayer ceramic circuit board with embedded circuitry for operating the component; the second substrate has a heat sink or conductive heat spreader mounted thereon. Thermoelectric (TEC) plates (Peltier devices) and temperature control circuitry are mounted between the first and second substrates to provide improved temperature control of semiconductor devices. A hermetic enclosure can be adhered to the metal support board.

The use of LTCC-M technology can also utilize the advantages of flip chip packaging together with integrated heat sinking. The packages can be made smaller, cheaper and more efficient than existing present-day packaging. The metal substrate serves as a heat spreader or heat sink. The flip chip can be mounted directly on the metal substrate, which is an integral part of the package, eliminating the need for additional heat sinking. A flexible circuit can be mounted over the bumps on the flip chip. The use of multilayer ceramic layers can also accomplish a fan-out and routing of traces to the periphery of the package, further improving heat sinking. High power integrated circuits and devices that have high thermal management needs can be used with LTCC-M technology.

An alternative exemplary LED package according to an embodiment of the present invention may comprise a metal layer, a printed wiring board (PWB) having one or more layers and one or more apertures, wherein the printed wire board overlies the metal layer, one or more isolators or interposers are in registration with the apertures of the PWB and mounted on the metal layer, and one or more LED die are mounted on the isolator wherein the isolator comprises a material having a coefficient of thermal expansion (TCE) that matches that of the one or more LED die mounted thereon. Preferably, the metal layer may comprise copper. Optionally, an encapsulant may be disposed over the one or more LED die. According to another option, the LED assembly may further comprise a reflector attached to the PWB. The details of this embodiment is described in detail with reference to FIG. 7, FIG. 8 and FIG. 9 below.

It can now be seen that in one aspect, the invention comprises an assembly of multicolor light emitting diodes packaged for improved color mixing. The packaged assembly comprises a thermally conductive mounting base including a surface cavity. A plurality of LED dies are mounted within the cavity, respective dice of the plurality emitting light of respectively different color. Overlying the LED die is a transparent material including light dispersing particles to randomly mix light from different LED dies. Advantageously, the transparent material is in the shape of a dome. It is also advantageous that the transparent material comprises encapsulant material.

The LED dice are advantageously mounted in a closely-packed configuration. The dice can comprise one or more red die, one or more green die, and one or more blue die. If there are a plurality of dice of one or more color, the dice are desirably arranged to minimize same color adjacency.

Additionally, the light dispersing particles are desirably deposited on a tacky layer or monolayer deposited directly on the LED die.

Desirably, the thermally conductive mounting base may comprise a ceramic-coated metal and the surface cavity comprises an opening in the ceramic.

It is understood that the above-described embodiments are illustrative of only a few of the many possible specific embodiments, which can represent applications of the invention. Numerous and varied other arrangements can be made by those skilled in the art without departing from the spirit and scope of the invention.

Furthermore, the multicolor LEDs package assembly alternatively includes base metal layer disposed underlying an apertured multilayer PWB with an interposer (TCE of interposes match up that of one or more LED die) disposed between a base metal layer and one or more LED die. Optimally, the LED die maybe mounted directed on a base metal layer having a TCE that closely matches that of the one or more LED die.

What is claimed is:

1. An assembly of colored light emitting diodes packaged for improved color mixing comprising:
a thermally conductive mounting base;
a plurality of LED dice mounted on the base, the plurality comprising one or more dies that emit light of a first color and one or more dies that emit light of a second color; and
a transparent material overlying the LED dice, said material including light dispersing particles to randomly mix light emitted by the plurality of LED dies.

2. The assembly of claim 1 wherein the transparent material comprises an encapsulant material.

3. The assembly of claim 1 wherein the transparent material is in the shape of a dome.

4. The assembly of claim 1 wherein the plurality of LED dice are mounted in a closely packed configuration.

5. The assembly of claim 4 wherein the closely packed configuration of LED dice comprises die to die gaps in the range between about 25 and about 2,000 microns.

6. The assembly of claim 4 wherein the closely packed configuration of LED dice comprises die to die gaps in the range between about 125 and about 500 microns.

7. The assembly of claim 1 wherein the plurality of LED dice comprise one or more red light emitting die, one or more green light emitting die and one or more blue light emitting die.

8. The assembly of claim 1 wherein the plurality of LED dice are arranged to minimize same color adjacency.

9. The assembly of claim 8 wherein the incidence of same color adjacency is approximately 60% or less.

10. The assembly of claim 5 wherein the plurality of LED dice are arranged to have an incidence of same color adjacency of approximately 60% or less.

11. The assembly of claim 1 further comprising an apertured printed wire board overlying the thermally conductive mounting base, wherein one or more apertures are in registration with the plurality of LED dice.

12. The assembly of claim 1 wherein the thermally conductive mounting base comprises a metal layer, a ceramic layer disposed on the metal layer, and a surface cavity comprising an opening in the ceramic layer.

13. The assembly of claim 1 wherein the light dispersing particles comprise particles of material selected from the group consisting of fumed silica, silicon, titanium oxide, indium oxide, tin oxide and combinations thereof.

14. The assembly of claim 1 wherein the light dispersing particles comprise particles that are spherical, pyramidal or flat in shape, or combinations thereof.

15. The assembly of claim 1 wherein the light dispersing particles comprise particles having average diameters in the range 0.01 to 100 microns.

16. The assembly of claim 1 wherein the light dispersing particles deflect light at an angle in the range from about 2° to about 25°.

17. The assembly of claim 1 wherein the light dispersing particles deflect light by reflection or refraction.

18. The assembly of claim 1 wherein the light dispersing particles are dispersed throughout the transparent material.

19. The assembly of claim 1 wherein the light dispersing particles are dispersed around the outer boundary of the transparent material.

20. The assembly of claim 1 further comprising an interposer disposed between the base and at least one of the LED die, said interposer comprising a material having a thermal coefficient of expansion approximately equivalent to a coefficient of thermal expansion of the LED die.

21. The assembly of claim 20 wherein the interposer is attached to the base with conductive epoxy, solder, brazing or mechanical means.

22. The assembly of claim 20 wherein the interposer comprises material selected from the group consisting of copper, copper—molybdenum—copper, tungsten—copper, aluminum-silicon-carbide, aluminum nitride, silicon, beryllium oxide, and diamond.

23. An assembly of colored light emitting diodes packaged for improved color mixing comprising:
a ceramic-coated metal base including an opening in the ceramic forming a surface cavity; and
a plurality of LED dice mounted within the cavity in thermal contact with the metal base, the plurality comprising one or more dies that emit light of a first color and one or more dies that emit light of a second color, said die mounted in closely packed relation with an incidence of same color adjacency of approximately 60% or less 23.

24. The assembly of claim 23 wherein the LED dies are arranged with die to die gaps in the range between about 25 microns and about 2,000 microns.

25. The assembly of claim 23 wherein the LED dies are arranged with die to die gaps in the range between about 125 microns and about 500 microns.

26. The assembly of claim 23 further comprising a transparent material including light dispersing particles to randomly mix light from different LED dies.

27. An assembly of colored light emitting diodes packages for improved color mixing comprising:
a low temperature co-fired ceramic-on-metal (LTCC-M) base, said base including a surface cavity;
a plurality of LED dice mounted within the cavity, the plurality comprising one or more dies that emit light of a first color and one or more dies that emit light of a second color; and
a transparent material overlying the plurality of LED dice, said material including light dispersing particles to randomly mix light emitted by the plurality of LED dies.

28. The assembly of claim 27 wherein each of said LED die has a pair of electrodes overlying and electrically insulated from the metal base.

29. The assembly of claim 28 further comprising conductive vias insulated from the base wherein the electrodes are electrically connected to the vias.

30. The assembly of claim 27 further includes wire bonds to electrically connect the electrodes to the base.

31. The assembly of claim 27 further comprising thermal connective pads mounted to the base to dissipate heat from the LED die.

32. An assembly of colored light emitting diodes packaged for improved color mixing comprising:
a thermally conductive mounting base;
a plurality of LED dice mounted on the base, the plurality comprising one or more dies that emit light of a first color and one or more dies that emit light of a second color; and
a layer comprising light dispersing particles deposited on the plurality of LED dice.

33. The assembly of claim 32 where in the layer comprises a monolayer.

34. The assembly of claim 32 further comprising a transparent material overlying the LED die and the layer.

35. The assembly of claim 32 wherein layer of light dispersing particle is adhered to the LED.

36. The assembly of claim 32 wherein the layer includes a tacky transparent material.

37. The assembly of claim 36 wherein the tacky transparent material is a resin having an index of refraction between the indices of refraction of the LED and the particles.

38. The assembly of claim 37 wherein the index of refraction of the resin is in a range between about 1.77 and about 3.0.

39. The assembly of claim 37 wherein the tacky transparent material is a silicone.

40. The assembly of claim 32 wherein the light dispersing particles comprise a frequency converting phosphor.

41. The assembly of claim 32 wherein the light dispersing particles comprise particles of material selected from the group consisting of fumed silica, silicon, titanium oxide, indium oxide, tin oxide and combinations thereof.

42. The assembly of claim 32 wherein the plurality of LED dice are arranged to minimize the same color adjacency.

43. The assembly of claim 42 wherein the plurality of LED dice are mounted in a closely packed configuration.

44. The assembly of claim 43 wherein the closely packed configuration of LED dice comprises die to die gaps in the range between about 25 and about 2,000 microns.

45. The assembly of claim 44 wherein the plurality of LED dice are arranged to have an incidence of same color adjacency of approximately 60% or less.
